(19) United States
(12) Patent Application Publication
(10) Pub. No.: US 2024/0251617 A1
(43) Pub. Date: Jul. 25, 2024

(54) VIA LAYER IN TRANSMISSION AREA AND DISPLAY DEVICE INCLUDING THE SAME

(71) Applicant: Samsung Display Co., LTD., Yongin-si (KR)

(72) Inventor: In Young JUNG, Yongin-si (KR)

(21) Appl. No.: 18/484,506

(22) Filed: Oct. 11, 2023

(30) Foreign Application Priority Data
Jan. 19, 2023 (KR) 10-2023-0008319

(51) Int. Cl. H10K 59/131; H10K 59/121

(52) U.S. Cl. CPC H10K 59/131; H10K 59/1213; H10K 2102/351

(57) ABSTRACT

A display device includes a main display area and a sub-display area adjacent to each other, a transistor in the main display area, a light emitting element which is in the sub-display area and electrically connected to the transistor, the light emitting element including a first electrode, a light emitting layer and a second electrode, a connection line which extends from the main display area to the sub-display area and connects the transistor to the light emitting element, and a via layer between the transistor and the light emitting element. The via layer has a first thickness overlapping the first electrode together with having a second thickness which overlaps the connection line and is smaller than the first thickness.

This application claims priority to Korean Patent Application No. 10-2023-0008319 filed on Jan. 19, 2023, and all the benefits accruing therefrom under 35 U.S.C. 119, the contents of which in its entirety are herein incorporated by reference.

### BACKGROUND

### 1. Field

The present disclosure relates to a display device.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions. The display device may include a display panel including a plurality of pixels connected to scan lines, data lines, and power lines to display an image. In addition, the display device may include various optical devices, such as an image sensor for capturing an image of the front side, a proximity sensor for detecting whether a user is located close to the front side of the display device, an illumination sensor for detecting illumination of the front side of the display device, and an iris sensor for recognizing an iris of a user. The optical device may be in a hole on the front surface of the display device that does not overlap with the display panel.

With diversification of electronic devices employing display devices, the display devices are provided in various designs. For example, in the smartphone, a display device capable of widening a display area omits a hole on the front surface of the display device. Optical devices in a hole on the front surface of the display device may be to overlap the display panel.

### SUMMARY

When an optical device such as an electro-optical device overlaps a display panel of a display device, at a hole defined in the display device, light incident on the optical device may be reduced since the optical device is covered by various elements of the display panel such as pixels, scan lines, data lines, power lines, etc. As a result, the function of the optical device may be degraded.

Aspects of the present disclosure provide a display device capable of preventing light incident on the optical device from being reduced even when the optical device is to overlap the display panel.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, a display device includes a substrate defining a main display area and a sub-display area, a transistor on the substrate in the main display area, a connection line on the transistor and extending from the main display area to the sub-display area, a via layer on the connection line, and light emitting elements on the via layer in the sub-display area and comprising a first electrode electrically connected to the connection line, a light emitting layer and a second electrode, where the via layer has a first thickness in an area overlapping the first electrode and has a second thickness in an area overlapping the connection line, and where the second thickness is smaller than the first thickness.

In an embodiment, the via layer includes a first area overlapping the first electrode in the sub-display area, and a second area not overlapping the first electrode and overlapping the connection line.

In an embodiment, the first area has the first thickness and the second area has the second thickness.

In an embodiment, the connection line overlaps the first area and the second area.

In an embodiment, the display device further includes a bank covering a portion of the first electrode and partitioning an emission area as a light emission area and a transmission area as a light transmission area, where the first area overlaps the emission area and the second area overlaps the transmission area.

In an embodiment, the via layer includes an opening area in an area other than the first area and the second area, where the opening area overlaps the transmission area.

In an embodiment, the display device further includes an interlayer insulating layer between the substrate and the connection line, where the opening area exposes the interlayer insulating layer.

In an embodiment, the first area overlaps the emission area.

In an embodiment, the via layer is continuously in the main display area and the sub-display area, and where the first thickness is the same as the thickness in the main display area.

In an embodiment, the display device further includes connection electrodes between the via layer and the first electrode, where the connection line electrically connects the transistor and the first electrode through the connection electrodes.

In an embodiment, the connection line includes a transparent conductive oxide.

According to an aspect of the present disclosure, a display device includes a substrate defining a main display area and a sub-display area, a transistor on the substrate in the main display area, a connection line on the transistor and extending from the main display area to the sub-display area, a first via layer on the connection line, a second via layer on the first via layer, and light emitting elements on the second via layer in the sub-display area and comprising a first electrode electrically connected to the connection line, a light emitting layer and a second electrode, where each of the first via layer and the second via layer has a smaller thickness in an area overlapping connection line than a thickness in an area overlapping the first electrode.

In an embodiment, the first via layer includes a first area overlapping the first electrode in the sub-display area and a second area not overlapping the first electrode and overlapping the connection line, and where the second via layer includes a third area overlapping the first electrode in the sub-display area and a fourth area not overlapping the first electrode and overlapping the connection line.

In an embodiment, the first area has a first thickness, the second area has a second thickness smaller than the first thickness, the third area has a third thickness, and the fourth area has a fourth thickness smaller than the third thickness.

In an embodiment, the first area of the first via layer overlaps the third area of the second via layer, and where the second area of the first via layer overlaps the fourth area of the second via layer.

In an embodiment, the display device further includes a bank covering a portion of the first electrode and partitioning an emission area and a transmission area, where the first area and the third area overlap the emission area, and where the second area and the fourth area overlap the transmission area.

In an embodiment, the first via layer includes a first opening area in an area other than the first area and the second area, and where the first opening area overlaps the fourth area of the second via layer and the transmission area.

In an embodiment, the display device further includes an interlayer insulating layer between the substrate and the connection line, where the first opening area exposes the interlayer insulating layer, and where the second via layer is in contact with the interlayer insulating layer.

In an embodiment, the first via layer includes a first opening area in an area other than the first area and the second area, where the second via layer includes a second opening area in an area other than the third area and the fourth area, and where the first area and the second area overlap each other.

According to an aspect of the present disclosure, a display device includes a substrate defining a main display area and a sub-display area, a transistor on the substrate in the main display area, a connection line on the transistor and extending from the main display area to the sub-display area, a first via layer on the connection line, a second via layer on the first via layer, and light emitting elements on the second via layer in the sub-display area and comprising a first electrode electrically connected to the connection line, a light emitting layer and a second electrode, where the second via layer has a first thickness in an area overlapping the first electrode and has a second thickness smaller than the first thickness in an area overlapping the connection line.

In an embodiment, the second via layer includes a first area overlapping the first electrode in the sub-display area and a second area not overlapping the electrode and overlapping the connection line, and where the first area has the first thickness and the second area has the second thickness.

In an embodiment, the display device further includes a bank covering a portion of the first electrode and partitioning an emission area and a transmission area, where the first area overlaps the emission area and the second area overlaps the transmission area.

In an embodiment, the second via layer includes an opening area in an area other than the first area and the second area, and where the opening area overlaps the transmission area.

In an embodiment, the first via layer has the same thickness in an area overlapping the first area, the second area and the opening area of the second via layer.

A display device according to an embodiment may improve transmittance of light incident to optical devices by reducing or removing the thickness of a via layer in a transmission area.

In addition, by disposing the via layer having a relatively small thickness in a region overlapping the connection line in the transmission area, it is possible to improve light transmittance and prevent a short circuit due to a pattern defect of a first electrode of the light emitting element.

However, the effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view illustrating a display device according to an embodiment;

FIG. 2 is an exploded perspective view showing a display device according to an embodiment;

FIG. 3 is a plan view illustrating a display panel, a display circuit board, a display driving circuit, and a touch driving circuit according to an embodiment;

FIG. 4 is a plan view illustrating a display panel, a display circuit board, a display driving circuit, and a touch driving circuit according to an embodiment;

FIG. 5 is an enlarged plan view of a portion of a display panel according to an embodiment;

FIG. 6 is an enlarged cross-sectional view of a display panel according to an embodiment;

FIG. 7 is an enlarged cross-sectional view of a display panel according to an embodiment;

FIG. 8 is a cross-sectional view taken along line I-I′ of FIG. 5;

FIG. 9 is a cross-sectional view taken along line II-II′ of FIG. 5;

FIG. 10 is a cross-sectional view showing an embodiment of the display panel taken along line I-I′ of FIG. 5;

FIG. 11 is a cross-sectional view showing an embodiment of the display panel taken along line II-II′ of FIG. 5;

FIG. 12 is a cross-sectional view showing an embodiment of the display panel taken along line I-I′ of FIG. 5;

FIG. 13 is a cross-sectional view showing an embodiment of the display panel taken along line II-II′ of FIG. 5;

FIG. 14 is a cross-sectional view showing an embodiment of the display panel taken along line I-I′ of FIG. 5; and

FIG. 15 is a cross-sectional view showing an embodiment of the display panel taken along line II-II′ of FIG. 5.

### DETAILED DESCRIPTION

The present disclosure will now be described more fully hereinafter with reference to the accompanying drawings, in which embodiments of the invention are shown. This invention may however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being related to another element such as being “on” or “connected to” another layer or substrate, it can be directly on the other layer or substrate, or intervening layers may also be present. In contrast, when a layer is referred to as being related to another element such as being “directly on” or “directly connected to” another layer or substrate, no intervening layer or element is present therebetween.

The same reference numbers indicate the same components throughout the specification. Within the Figures and the text of the disclosure, a reference number indicating a singular form of an element may also be used to reference a plurality of the singular element.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Each of the features of the various embodiments of the present disclosure may be combined or combined with each other, in part or in whole, and technically various interlocking and driving are possible. Each embodiment may be implemented independently of each other or may be implemented together in an association.

Hereinafter, embodiments will be described with reference to the accompanying drawings.

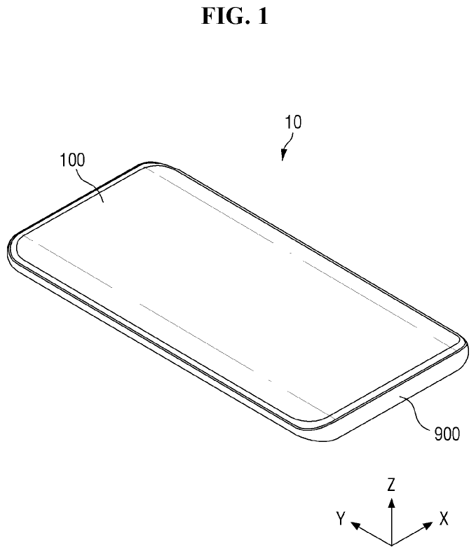

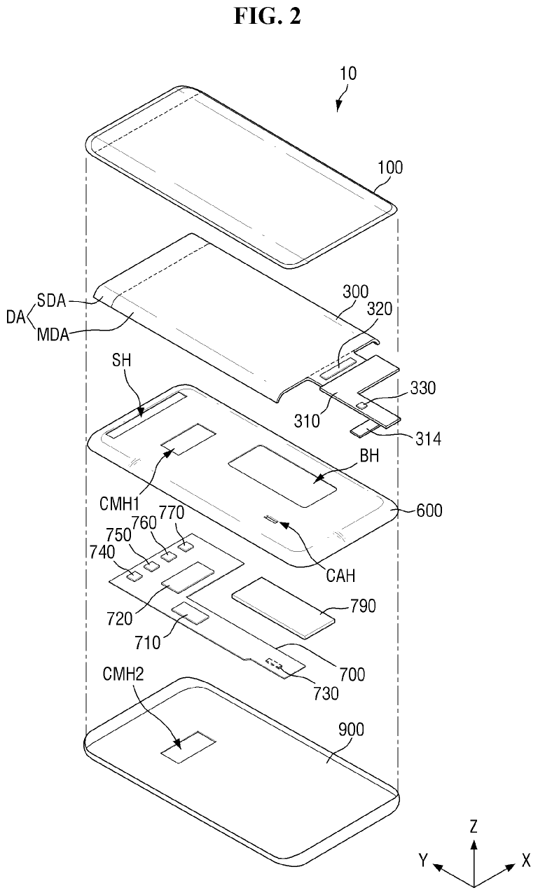

FIG. 1 is a perspective view illustrating a display device 10 according to an embodiment. FIG. 2 is an exploded perspective view showing a display device 10 according to an embodiment.

Referring to FIGS. 1 and 2, a display device 10 according to an embodiment may be applied to portable electronic devices such as a mobile phone, a smartphone, a tablet personal computer, a mobile communication terminal, an electronic organizer, an electronic book, a portable multimedia player (PMP), a navigation system, an ultra mobile PC (UMPC) or the like. Alternatively, the display device 10 according to an embodiment may be applied as a display unit of a television, a laptop, a monitor, a billboard, or an Internet-of-Things (IoT) terminal. Alternatively, the display device 10 according to an embodiment may be applied to wearable devices such as a smart watch, a watch phone, a glasses type display, or a head mounted display (HMD). Alternatively, the display device 10 according to an embodiment may be applied to a dashboard of a vehicle, a center fascia of a vehicle, a center information display (CID) disposed on a dashboard of a vehicle, a room mirror display in place of side mirrors of a vehicle, or a display disposed on a rear surface of a front seat for rear seat entertainment of a vehicle.

In the present disclosure, a first direction (X-axis direction) may be a short side direction of the display device 10, for example, a horizontal direction of the display device 10 in a plan view. A second direction (Y-axis direction) may be a long side direction of the display device 10, for example, a vertical direction of the display device 10 in a plan view. A plane may be defined by the first direction and the second direction crossing or intersecting each other. A third direction (Z-axis direction) may be a thickness direction of the display device 10. A “plan view” may be a view of the plane, along a direction which crosses or is normal to the plane, such as along the third direction.

The display device 10 may have a planar shape similar to a rectangular shape. For example, the display device 10 may have a planar shape similar to a rectangular shape having short sides in the first direction (X-axis direction) and long sides in the second direction (Y-axis direction), as shown in FIG. 1. A corner where the short side in the first direction (X-axis direction) and the long side in the second direction (Y-axis direction) meet each other, may be right-angled or rounded with a predetermined curvature, in the plan view. The planar shape of the display device 10 is not limited to a rectangular shape, and may be formed in a planar shape similar to another polygonal shape, a circular shape, or elliptical shape.

The display device 10 may be formed flat. As being flat, the display device 10 may be disposed in a plane defined by two directions crossing each other The display device 10 may include a front surface which is flat, in a plane. Alternatively, the display device 10 may be formed such that two sides facing (or opposite to) each other are bent, curved, inclined, etc. relative to the plane and/or the front surface in such plane. For example, the display device 10 may be formed or provided such that the left and right sides are bent relative to the front surface of the display device 10. Alternatively, the display device 10 may be formed such that all of the upper, lower, left, and right sides are bent relative to the front surface. In an embodiment, one or more sides of the display device 10 which extend from the front surface may be bendable, curvable, foldable, etc. relative to the front surface.

The display device 10 according to an embodiment includes a cover window 100, a display panel 300, a display circuit board 310, a display driving circuit 320, a bracket 600, a main circuit board 700, optical devices 740, 750, 760, and 770, and a lower cover 900.

The cover window 100 may be disposed above the display panel 300 along the third direction, to cover the front surface of the display panel 300. Accordingly, the cover window 100 may function to protect the front surface of the display panel 300. The cover window 100 may define the front surface of the display device 10, without being limited thereto.

The display panel 300 may be disposed below the cover window 100, along the third direction. The display panel 300 may include a display area DA including a main display area MDA and a sub-display area SDA. The main display area MDA may occupy most of the display area DA, that is, may have a planar area which is most of the total planar area of the display area DA. The sub-display area SDA may be disposed on one side of the main display area MDA, for example, above the main display area MDA as shown in FIG. 2, but is not limited thereto. That is, the sub-display area SDA may extend from the main display area MDA, and be further in the Y-axis direction along the plane defined by the X-axis direction and the Y-axis direction crossing each other, than the main display area MDA. A boundary may be defined between the main display area MDA and the sub-display area SDA, as shown with a dotted line in FIG. 2.

The main display area MDA may not include a transmission area TA that transmits light (e.g., a light transmission area), but may include only a pixel area including pixels PX for displaying an image. In contrast, the sub-display area SDA may include both a transmission area TA through which light is transmitted and a pixel area including pixels PX for displaying an image. Therefore, the light transmittance of the sub-display area SDA may be higher than that of the main display area MDA.

The sub-display area SDA may overlap the optical devices 740, 750, 760, and 770 in (or along) the third direction (Z-axis direction). Therefore, light passing through the sub-display area SDA may be incident to the optical devices 740, 750, 760, and 770, so that light incident from the front surface of the display device 10 may be sensed even when each of the optical devices 740, 750, 760, and 770 in the display panel 300 is disposed overlapping with portions of the display panel 300. The light passing through the sub-display area SDA may be incident from outside the display device 10, such as to define external light.

The display panel 300 may be a light emitting display panel including a light emitting element. For example, the display panel 300 may be an organic light emitting display panel using an organic light emitting diode including an organic light emitting layer, and a micro light emitting diode display panel using a micro light emitting diode (LED), a quantum dot light emitting display panel using a quantum dot light emitting diode including a quantum dot light emitting layer, or an inorganic light emitting display panel using an inorganic light emitting element including an inorganic semiconductor. Hereinafter, a case where the display panel 300 is an organic light emitting display panel will be mainly described.

The display circuit board 310 and the display driving circuit 320 may be attached to the display panel 300 at one side or a same side of the display panel 300. The display circuit board 310 may be a flexible printed circuit board which is bendable, a rigid printed circuit board which is rigid to be hardly bent, or a composite printed circuit board having characteristics of both of the rigid printed circuit board and the flexible printed circuit board.

The display driving circuit 320 may receive electrical signals such as control signals and power voltages through the display circuit board 310 to generate and output signals and voltages for driving the display panel 300. The display driving circuit 320 may be formed of or include an integrated circuit (IC) which is attached on the display panel 300 by a chip-on-glass (COG) method, a chip-on-plastic (COP) method, or an ultrasonic bonding method, but the present disclosure is not limited thereto. For example, the display driving circuit 320 may be attached onto the display circuit board 310.

A touch driving circuit 330 may be disposed on the display circuit board 310. The touch driving circuit 330 may be formed of or include an IC to be attached to the display circuit board 310 at the top surface of the display circuit board 310. The touch driving circuit 330 may be electrically connected to touch electrodes of a touch sensor layer of the display panel 300, through the display circuit board 310. The touch driving circuit 330 may output an electrical signal such as a touch driving signal to the touch electrodes and sense the voltage charged in the capacitances of the touch electrodes.

The touch driving circuit 330 may generate touch data according to the change in the electrical signal sensed at each of the touch electrodes to transmit the touch data to a main processor 710. Then, the main processor 710 may analyze the touch data to generate touch coordinates of an external input. The external input may include a contact touch and/or a proximity touch of an input tool. The contact touch indicates that an input tool as a body part (e.g., a human finger) or pen makes a direct contact with the cover window 100 disposed above a sensor electrode layer. The proximity touch indicates that the input tool is positioned above the cover window 100 to be proximately apart therefrom, such as hovering.

Further, a power supply unit may be additionally disposed on the display circuit board 310 to supply electrical signals such as display driving voltages for driving the display driving circuit 320.

The bracket 600 may be disposed under the display panel 300. The bracket 600 may include plastic, metal, or both plastic and metal. The bracket 600 may include a first camera hole CMH1 into which a first camera sensor 720 is inserted or extended, a battery hole BH in which a battery 790 is disposed, a cable hole CAH through which a cable 314 connected to the display circuit board 310 passes, and a light-transmitting hole SH in which one or more of the optical devices 740, 750, 760, and 770 are disposed. Alternatively, the bracket 600 may be formed so as not to overlap a sub-display area SDA of the display panel 300 by excluding the light-transmitting hole SH corresponding to the sub-display area SDA.

The main circuit board 700 and a battery 790 may be disposed under the bracket 600. The main circuit board 700 may be a printed circuit board or a flexible printed circuit board.

The main circuit board 700 may include the main processor 710, the first camera sensor 720, a main connector 730, and the optical devices 740, 750, 760, and 770. The optical devices 740, 750, 760, and 770 may include a proximity sensor 740, an illumination sensor 750, an iris sensor 760 as a body part sensor (e.g., an iris of a human body), and a second camera sensor 770. One or more of the optical devices 740, 750, 760, and 770 may define an electro-optical sensor which uses an electrical signal and/or light to provide a function to display device 10.

The first camera sensor 720 may be disposed on both the top and bottom surfaces of the main circuit board 700, the main processor 710 may be disposed on the top surface of the main circuit board 700, and the main connector 730 may be disposed on the bottom surface of the main circuit board 700. The proximity sensor 740, the illumination sensor 750, the iris sensor 760, and the second camera sensor 770 may be disposed on the top surface of the main circuit board 700.

The main processor 710 may control all functions of the display device 10. For example, the main processor 710 may output electrical signals such as digital video data to the display driving circuit 320, through the display circuit board 310, such that the display panel 300 displays an image. Further, the main processor 710 may receive electrical signals such as touch data from the touch driving circuit 330 and determine the “touch coordinates, and then execute an application indicated by an icon displayed at the” touch coordinates. Furthermore, the main processor 710 may convert electrical signals such as first image data inputted from the first camera sensor 720 into other electrical signals such as digital video data, and output such signals to the display driving circuit 320 through the display circuit board 310, thereby displaying an image captured by the first camera sensor 720, on the display panel 300. In addition, the main processor 710 may control the display device 10 according to electrical signals such as sensor signals input from the proximity sensor 740, the illumination sensor 750, the iris sensor 760, and/or the second camera sensor 770.

The main processor 710 may determine whether there exists an object as an input tool in the proximity of the front surface of the display device 10 in accordance with a proximity sensor signal input thereto from a proximity sensor 740. If there exists an object in the proximity of the front surface of the display device 10 during a call mode of the display device 10 where a user talks to another person with the use of the display device 10, the main processor 710 may not execute an application corresponding to an icon at the touch coordinates of the touch even as an input event.

The main processor 710 may determine the brightness of the front surface of the display device 10 based on an illumination sensor signal input thereto from an illumination sensor 750. The main processor 710 may adjust the luminance of an image displayed by the display panel 300, in accordance with the brightness of the front surface of the display device 10.

The main processor 710 may determine whether an iris image of a body part such as an eye iris of the user is identical to a previously-stored iris image based on an iris sensor signal input thereto from an iris sensor 760. If the iris image of the user is identical to the previously-stored iris image, the main processor 710 may unlock the display device 10 and may display a home screen on the display panel 300. Such sensor may provide a biometric function to the display device 10, in which a body part image is captured and analyzed to determine if the body part image matches a reference body part image, such as for locking or unlocking the display device 10, denying or providing access to an application or information within the display device 10, etc.

The main processor 710 may generate digital video data based on second image data received from the second camera sensor 770. The main processor 710 may display an image captured by the second camera sensor 770 by outputting the digital video data to the display driving circuit 320 via the display circuit board 310.

The first camera sensor 720 may process a still or moving image obtained by an image sensor and may output the processed image to the main processor 710. The first camera sensor 720 may be a complementary metal-oxide-semiconductor (CMOS) image sensor or a charge-coupled device (CCD) image sensor. The first camera sensor 720 may be exposed to outside the display device 10 at the bottom of the lower cover 900, by a second camera hole CMH2, and may thus be able to capture an image of an object or the background below the display device 10.

The cable 314, which passes through the cable hole CAH of the bracket 600 from a rear thereof to a front thereof, may be connected to the main connector 730. Accordingly, the main circuit board 700 may be electrically connected to the display circuit board 310.

The proximity sensor 740 may be a sensor for detecting whether there exists an object in the proximity of the front surface of the display device 10. For example, the proximity sensor 740 may include a light source that outputs light and a light receiver that receives light reflected from an object. The proximity sensor 740 may determine the presence of an object in the proximity of the front surface of the display device 10 based on the amount of light reflected from the object. As the proximity sensor 740 is disposed to overlap, in the third direction (Z-axis direction), with the light-transmitting hole SH, the sub-display area SDA of the display panel 300 and the cover window 100, the proximity sensor 740 may generate a proximity sensor signal based on whether there exists an object in the proximity of the front surface of the display device 10 and may output the generated proximity sensor signal to the main processor 710.

The illumination sensor 750 may be a sensor for detecting the brightness at the front surface of the display device 10. The illumination sensor 750 may include a resistor whose resistance varies depending on the brightness of light incident thereupon. The illumination sensor 750 may determine the brightness at the front surface of the display device 10 based on the resistance of the resistor. As the illumination sensor 750 is disposed to overlap, in the third direction (Z-axis direction), with the light-transmitting hole SH, the sub-display area SDA of the display panel 300 and the cover window 100, the illumination sensor 750 may generate an illumination sensor signal based on the brightness at the front surface of the display device 10 and may output the generated illumination sensor signal to the main processor 710.

The iris sensor 760 may be a sensor for sensing a biometric input for determining whether a captured iris image of the user is identical to an iris image stored in advance in a memory. As the iris sensor 760 is disposed to overlap, in the third direction (Z-axis direction), with the light-transmitting hole SH, the sub-display area SDA of the display panel 300 and the cover window 100, the iris sensor 760 may capture an image of the iris of the user above the display device 10. The iris sensor 760 may generate an iris sensor signal based on whether the captured iris image of the user is identical to the iris image stored in advance in the memory and may output the generated iris sensor signal to the main processor 710.

The second camera sensor 770 may process image frames obtained by an image sensor, such as a still or moving image, and may output the processed image frames to the main processor 710. The second camera sensor 770 may be a CMOS or CCD image sensor. The pixel quantity of the second camera sensor 770 may be smaller than the pixel quantity of the first camera sensor 720, and the size of the second camera sensor 770 may also be smaller than the size of the first camera sensor 720. As the second camera sensor 770 is disposed to overlap, in the third direction (Z-axis direction), with the light-transmitting hole SH, the sub-display area SDA of the display panel 300 and the cover window 100, the second camera sensor 770 may capture an image of an object or the background above the display device 10.

The battery 790 may be disposed not to overlap with the main circuit board 700 in the third direction (Z-axis direction). The battery 790 may overlap with the battery hole BH of the bracket 600. Referring to FIG. 2, the main circuit board 700 may have a recess in which the battery 790 is accommodated. The battery 790 and the main circuit board 700 may be adjacent to each other along a plane, such as to be coplanar with each other.

A mobile communication module, which can transmit wireless signals to, or receive wireless signals from, at least one of a base station, an external terminal, and a server via a mobile communication network may be further provided in the main circuit board 700. The wireless signals may be electrical signals including but not limited to audio signals, video call signals, and various types of data that can be transmitted with text/multimedia messages.

The lower cover 900 may be disposed below the main circuit board 700 and the battery 790. The lower cover 900 may be coupled to and fixed to the bracket 600. The lower cover 900 may form the bottom exterior of the display device 10. The lower cover 900 may be formed of plastic, a metal, or both plastic and metal.

The second camera hole CMH2, which exposes the bottom of the first camera sensor 720, may be formed in the lower cover 900. That is, portions of the lower cover 900 may define the second camera hole CMH2. In an embodiment, the first camera sensor 720 and the first and second camera holes CMH1 and CMH2 may be aligned with each other along the third direction. The location of the first camera sensor 720 and the locations of the first and second camera holes CMH1 and CMH2, which correspond to the first camera sensor 720, are not limited to those illustrated in FIG. 2.

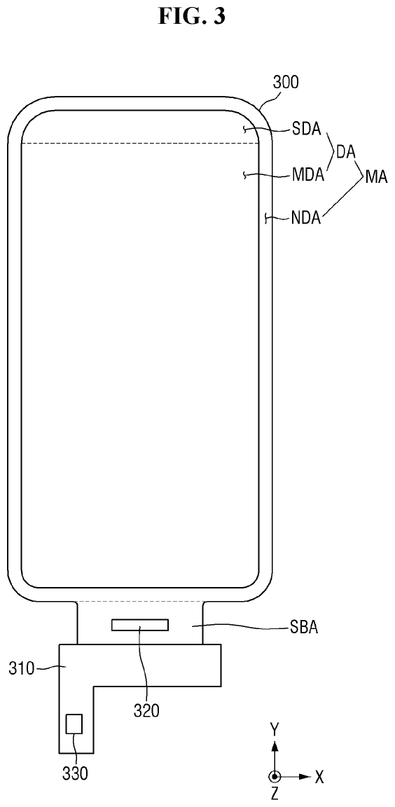

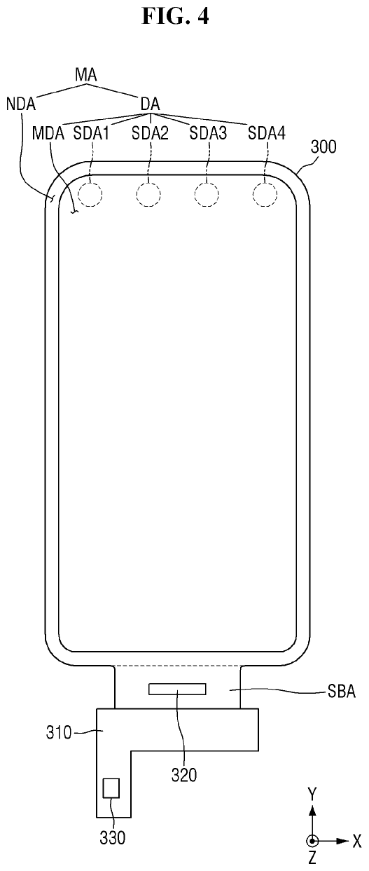

FIGS. 3 and 4 are plan views respectively illustrating a display panel 300, a display circuit board 310, a display driving circuit 320, and a touch driving circuit 330 according to an embodiment

Referring to FIG. 3, the display panel 300 may be a rigid display panel that is rigid and not easily bent or a flexible display panel that is flexible and can be easily bent, folded, or rolled. For example, the display panel 300 may be a foldable display panel which can be folded and unfolded, a curved display panel having a curved display surface, a bent display panel having a bent area other than the display surface, a rollable display panel which can be rolled up and rolled out and a stretchable display panel which can be stretched.

Further, the display panel 300 may be a transparent display panel which is transparently implemented to allow an object or background disposed behind the rear surface of the display panel 300 to be viewed from the front surface of the display panel 300 which is opposite to the rear surface. Further, the display panel 300 may be a reflective display panel which is capable of reflecting an object or background in front of the front surface of the display panel 300.

The display panel 300 may include a main region MA and a sub-region SBA which protrudes from a side of the main region MA. The main region MA may include a display area DA at which an image is displayed and a non-display area NDA that is a peripheral area of the display area DA. A planar area of the display area DA may occupy most of the main region MA. The display area DA may be disposed at the center of the main region MA. The non-display area NDA may be a planar area outside the display area DA, such as in the plan view. The non-display area NDA may be defined as an edge area of the display panel 300.

The display area DA may include a main display area MDA and a sub-display area SDA. The planar area of the main display area MDA may occupy most of the total planar area of the display area DA. Various components or layers of the display device 10 may include a main region MA, a sub-region SBA, a display area DA, a non-display area NDA, a main display area MDA, a sub-display area SDA, etc. corresponding to those described above.

The main display area MDA may not include a transmission area TA that transmits light, but may include only a pixel area including pixels PX for displaying an image. In contrast, the sub-display area SDA may include both a transmission area TA through which light is transmitted and a pixel area including pixels PX for displaying an image. Therefore, the light transmittance of the sub-display area SDA may be higher than that of the main display area MDA.

The sub-display area SDA may overlap or correspond to the optical devices 740, 750, 760, and 770 in the third direction (Z-axis direction). Therefore, light passing through the sub-display area SDA may be incident to the optical devices 740, 750, 760, and 770. Accordingly, light incident from outside the display device 10, at the front surface of the display device 10, may be sensed even when each of the optical devices 740, 750, 760, and 770 is the display panel 300 is disposed overlapping with various components or layers of the display panel 300.

The sub-display area SDA may be disposed on one side of the main display area MDA, for example, above the main display area MDA as shown in the plan view FIG. 3, but is not limited thereto. For example, the sub-display area SDA may be disposed on the left, right, or lower side of the main display area MDA, with respect to the plan view of FIG. 3. Alternatively, the sub-display area SDA may be disposed adjacent to the center of the main display area MDA and surrounded by portions of the main display area MDA in the plan view. Alternatively, the sub-display area SDA may be disposed adjacent to a corner of the display panel 300 in the plan view. Referring to FIG. 3, a same one of the sub-display area SDA may overlap or correspond to all of the electro-optical sensors (e.g., the optical devices 740, 750, 760, and 770).

Alternatively, the display area DA may include a plurality of sub-display areas SDA1, SDA2, SDA3, and SDA4 as shown in FIG. 4. The plurality of sub-display areas SDA1, SDA2, SDA3, and SDA4 may be spaced apart from each other within an overall planar area of the main display area MDA. Each of the plurality of sub-display areas SDA1, SDA2, SDA3, and SDA4 may be surrounded by the main display area MDA. That is, a separate sub-display area may be omitted in FIG. 4, by occupying a planar area within the overall planar area of the main display area MDA. Referring to FIGS. 3 and 4, one or more of the various sub-display areas may overlap a planar area of the display panel 300, such as to overlap (or correspond to) various components or layers of the display panel 300.

The first sub-display area SDA1 may overlap the proximity sensor 740 in the third direction (Z-axis direction). Therefore, the proximity sensor 740 may receive external light and sense the light incident from the front surface of the display device 10 through the first sub-display area SDA1, even though the proximity sensor 740 overlaps the display panel 300.

The second sub-display area SDA2 may overlap the illumination sensor 750 in the third direction (Z-axis direction). Therefore, the illumination sensor 750 may receive external light and sense light incident from the front of the display device 10 through the second sub-display area SDA2 even though the illumination sensor 750 overlaps the display panel 300.

The third sub-display area SDA3 may overlap the iris sensor 760 as a biometric sensor, in the third direction (Z-axis direction). Therefore, the iris sensor 760 may receive external light and sense light incident from the front surface of the display device 10 through the third sub-display area SDA3 even though the iris sensor 760 overlaps the display panel 300.

The fourth sub-display area SDA4 may overlap the second camera sensor 770 in the third direction (Z-axis direction). Therefore, the second camera sensor 770 may sense light incident from the front surface of the display device 10 through the fourth sub-display area SDA4 even though the second camera sensor 770 overlaps the display panel 300.

The display area DA may include four sub-display areas SDA1, SDA2, SDA3, and SDA4 as shown in FIG. 4, but is not limited thereto. The number of sub-display areas SDA1, SDA2, SDA3, and SDA4 may depend on the number of optical devices 740, 750, 760, and 770. The sub-display areas SDA1, SDA2, SDA3, and SDA4 may be disposed to correspond to the optical devices 740, 750, 760, and 770 in a one-to-one manner.

Each of the plurality of sub-display areas SDA1, SDA2, SDA3, and SDA4 may be formed in a circular planar shape as shown in FIG. 4, but is not limited thereto. For example, each of the plurality of sub-display areas SDA1, SDA2, SDA3, and SDA4 may be formed in a polygonal planar shape or an elliptical planar shape. Also, the plurality of sub-display areas SDA1, SDA2, SDA3, and SDA4 may have the same planar size as shown in FIG. 4, but are not limited thereto. The plurality of sub-display areas SDA1, SDA2, SDA3, and SDA4 may have different planar sizes.

The sub-region SBA may protrude in the second direction (Y-axis direction) from a side of the main region MA. As shown in FIG. 3, the length of the sub-region SBA in the first direction (X-axis direction) may be smaller than the length of the main region MA in the first direction (X-axis direction), and the length of the sub-region SBA in the second direction (Y-axis direction) may be smaller than the length of the main region MA in the second direction (Y-axis direction), but the present disclosure is not limited thereto. The sub-region SBA may be bendable to be bent. The display device 10 (or the display panel 300) which is bent at the sub-region SBA may dispose a portion of or all of the sub-region SBA facing the bottom surface of the display panel 300. In this case, the display panel 300 which is bent may dispose the sub-region SBA overlapping the main region MA in the third direction (Z-axis direction) of the display panel 300 which is bent.

The display panel 300 may be foldable at the sub-region SBA such that the sub-region SBA may be placed under the display panel 300. In this case, a portion of or all of the sub-region SBA of the display panel 300 may overlap the main region MA of the display panel 300 in the third direction (Z-axis direction).

The display circuit board 310 and the display driving circuit 320 may be attached to the display panel 300 at the sub-region SBA of the display panel 300. The display circuit board 310 may be attached onto pads (not shown) of the display panel 300 which are located at the sub-region SBA of the display panel 300, such as by using a low resistance and high reliability material such as an anisotropic conductive film, a self assembly anisotropic conductive paste (SAP) or the like. The touch driving circuit 330 may be disposed on the display circuit board 310.

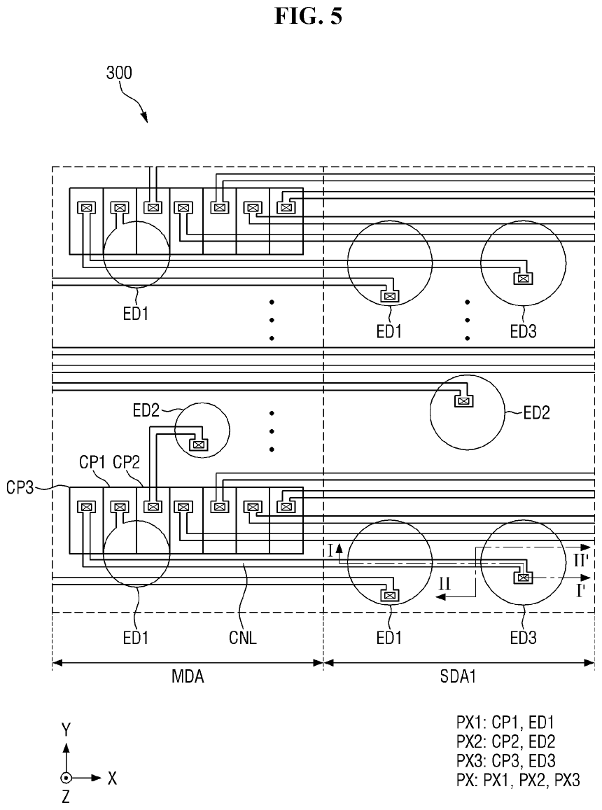

FIG. 5 is an enlarged plan view of a portion of a display panel 300 according to an embodiment. FIG. 5 illustrates an example of a portion of a main display area MDA relative to a first sub-display area SDA1 of a display panel 300.

Referring to FIG. 5, the display panel 300 may include a main display area MDA and a first sub-display area SDA1. The main display area MDA may be adjacent to the first sub-display area SDA1 and may be disposed to surround the first sub-display area SDA1.

The display panel 300 may include a plurality of pixels PX. The plurality of pixels PX may include a first pixel PX1 and a second pixel PX2 emitting light in the main display area MDA, and a third pixel PX3 emitting light in the first sub-display area SDA1. One or more among the first pixel PX1, second pixel PX2, and third pixel PX3 may be provided in plural within the display area DA. The first pixel PX1 may be a red pixel emitting red light, the second pixel PX2 may be a green pixel emitting green light, and the third pixel PX3 may be a blue pixel emitting blue light. However, the present disclosure is not limited thereto, and may further include a white pixel emitting white light.

The plurality of pixels PX may include a pixel circuit provided in plural including pixel circuits driving light emitting elements. For example, the first pixel PX1 may include a first pixel circuit CP1 that is connected to and drives the first light emitting element ED1, the second pixel PX2 may include a second pixel circuit CP2 that is connected to and drives the second light emitting element ED2, and the third pixel PX3 may include a third pixel circuit CP3 that is connected to and drives the third light emitting element ED3.

The first sub-display area SDA1 may overlap or correspond to the proximity sensor 740 shown in FIG. 2. That is, the first sub-display area SDA1 may be disposed in an area overlapping the proximity sensor 740 in the third direction (Z-axis direction). For example, light incident from the outside may pass through the first sub-display area SDA1 and be provided to the proximity sensor 740.

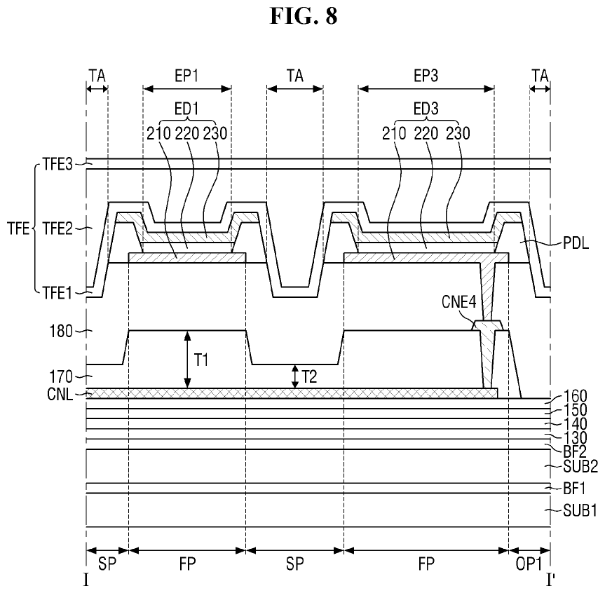

The first sub-display area SDA1 may have a smaller number of pixels than the main display area MDA in order to secure a planar area through which light incident from the outside can pass, that is, a transmission area TA. A planar area in the first sub-display area SDA1 where the third light emitting element ED3 is not disposed may be defined as a transmission area TA shown in FIG. 8. For example, in the first sub-display area SDA1, the planar area in which the first electrode of the third light emitting element ED3 and banks which surround the first electrode are not disposed or excluded, may be the transmission area TA. In an embodiment, when the bank represents a black color, the transmission area TA may be defined with respect to the bank, and a planar area outside of the bank in a plan view may be the transmission area TA. In addition, when the bank is transparent, the transmission area TA may be defined with respect to the first electrode of each light emitting element, may exclude the bank, and the planar area which is outside of the first electrode may be the transmission area TA shown in FIG. 8.

In an embodiment, the number of third pixels PX3 disposed in the first sub-display area SDA1 may be less than the number of the first pixels PX1 which is disposed in the main display area MDA. However, the present disclosure is not limited thereto, and the number of the third pixels PX3 disposed in the first sub-display area SDA1 may be the same as the number of the first pixels PX1 which is disposed in the main display area MDA.

The first pixel circuit CP1 of the first pixel PX1 and the second pixel circuit CP2 of the second pixel PX2 may both be disposed in the main display area MDA, and the third pixel circuit CP3 of the third pixel PX3 may not be disposed in the first sub-display area SDA1. In this case, since the components of the various pixel circuits which may block or interfere with passage of light are omitted from the first sub-display area SDA1, the light transmittance of the first sub-display area SDA1 may be greater than that of the main display area MDA.

Referring to FIG. 5, a respective light emitting element may be connected to a corresponding pixel circuit by overlapping structures (like the first light emitting element ED1 overlapping the first pixel circuit CP1 in FIG. 5) or by non-overlapping structures (like the second light emitting element ED2 connected to the second pixel circuit CP2 by a second connection line therebetween). For any light emitting element in a respective sub-display area, a corresponding connection line may be used for connection to a corresponding pixel circuit (like each of the light emitting elements in the first sub-display area SDA1 in FIG. 5).

The third light emitting element ED3 in the first sub-display area SDA1 and the third pixel circuit CP3 in the main display area MDA, may be electrically connected to each other through a connection line CNL, such as a third connection line. The connection line CNL may extend from the main display area MDA to the first sub-display area SDA1 and may overlap the transmission area TA of the first sub-display area SDA1. The connection line CNL may include a transparent conductive line as a transparent signal line. The transparent conductive line may include a transparent conductive material or a light transmissive material. For example, the connection line CNL may formed of or include a transparent conductive oxide (TCO) film such as indium tin oxide (ITO), indium zinc oxide (IZO), indium gallium zinc oxide (IGZO), zinc oxide (ZnO), or indium oxide (In₂O₃).

The main display area MDA may be disposed adjacent to the first sub-display area SDA1 and may surround the first sub-display area SDA1. The main display area MDA may have a light transmittance lower than that of the first sub-display area SDA1. In the main display area MDA, each of the first pixel circuit CP1 and the first light emitting element ED1 of the first pixel PX1 and the second pixel circuit CP2 and the second light emitting element ED2 of the second pixel PX2 may be disposed. In addition, the third pixel circuit CP3 of the third pixel PX3 may be disposed in the main display area MDA. Accordingly, owing to the components of the various pixel circuits which may block or interfere with passage of light, the light transmittance of the main display area MDA may be lower than that of the first sub-display area SDA1.

The size of the light emitting elements disposed in the main display area MDA may be smaller than the size of the light emitting elements disposed in the first sub-display area SDA1, where such sizes are planar sizes. For example, the size of the first light emitting element ED1 disposed in the main display area MDA may be smaller than the size of the third light emitting element ED3 disposed in the first sub-display area SDA1. In addition, the size of the first electrode of the first light emitting element ED1 disposed in the main display area MDA may be smaller than the size of the first electrode of the third light emitting element ED3 disposed in the first sub-display area SDA1.

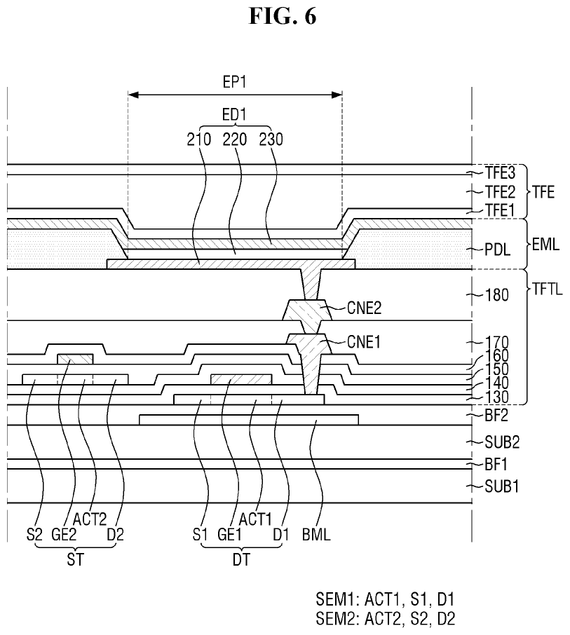

FIG. 6 is an enlarged cross-sectional view of a display panel 300 according to an embodiment. FIG. 6 illustrates a cross-section of the first pixel PX1 disposed in the main display area MDA of FIG. 5. The horizontal direction in FIG. 6 may represent various directions along the plane defined by the first and second directions crossing each other, while the vertical direction may represent the thickness direction.

Referring to FIG. 6, a first buffer layer BF1 may be disposed on a first substrate SUB1, a second substrate SUB2 may be disposed on the first buffer layer BF1, and a second buffer layer BF2 may be disposed on the second substrate SUB2. A thin film transistor layer TFTL, a light emitting element layer EML, and an encapsulation layer TFE may be sequentially disposed on the second buffer layer BF2.

Each of the first substrate SUB1 and the second substrate SUB2 may be formed of an insulating material such as glass, quartz, or polymer resin. For example, the first substrate SUB1 and the second substrate SUB2 may include polyimide. Each of the first substrate SUB1 and the second substrate SUB2 may be a flexible substrate which can be bent, folded or rolled.

Each of the first buffer layer BF1 and the second buffer layer BF2 are layers for protecting components and layers of thin film transistors of the thin film transistor layer TFTL and a light emitting layer 220 of the light emitting element layer EML from moisture permeating through the first substrate SUB1 and the second substrate SUB2 which are susceptible to moisture permeation. Various transistors of the thin film transistor layer TFTL may define various pixel circuits connected to respective light emitting elements. Each of the first buffer layer BF1 and the second buffer layer BF2 may be formed as a plurality of inorganic layers that are stacked. For example, each of the first buffer layer BF1 and the second buffer layer BF2 may be formed of multiple layers in which one or more inorganic layers of a silicon nitride layer, a silicon oxynitride layer, a silicon oxide layer, a titanium oxide layer and an aluminum oxide layer are alternately stacked.

A light blocking layer BML as a light blocking pattern may be disposed on the second substrate SUB2. The light blocking layer BML may be disposed to overlap a first active region ACT1 of a driving transistor DT to prevent leakage of an electrical current (e.g., a leakage current) occurring when light is incident on the first active region ACT1 of the driving transistor DT. Although FIG. 6 illustrates that the light blocking layer BML overlaps only the first active region ACT1 of the driving transistor DT, the present disclosure is not limited thereto, and the light blocking layer BML may also overlap a second active region ACT2 of a switching transistor ST.

The light blocking layer BML may be covered by the second buffer layer BF2. The light blocking layer BML may be formed as a single layer or multiple layers made of any one of molybdenum (Mo), aluminum (Al), chromium (Cr), gold (Au), titanium (Ti), nickel (Ni), neodymium (Nd), copper (Cu) and an alloy thereof.

The thin film transistor layer TFTL may include a driving transistor DT including a first semiconductor layer SEM1 and a first gate electrode GE1, a switching transistor ST including a second semiconductor layer SEM2 and a second gate electrode GE2, a gate insulating layer 130, a first interlayer insulating layer 140, a second interlayer insulating layer 150, a third interlayer insulating layer 160, a first via layer 170, a second via layer 180, a first connection electrode CNE1 and a second connection electrode CNE2.

The first semiconductor layer SEM1 may be formed on the second buffer layer BF2. The first semiconductor layer SEM1 may include polycrystalline silicon, monocrystalline silicon, low-temperature polycrystalline silicon, amorphous silicon, or an oxide semiconductor. The first semiconductor layer SEM1 may include a first source region S1, the first active region ACT1, and a first drain region D1 by ion doping.

The gate insulating layer 130 may be disposed on the first semiconductor layer SEM1. The gate insulating layer 130 may be formed of an inorganic layer, for example, a silicon nitride layer, a silicon oxynitride layer, a silicon oxide layer, a titanium oxide layer, or an aluminum oxide layer.

The first gate electrode GE1 may be disposed on the gate insulating layer 130. The first gate electrode GE1 may be a gate electrode of the driving transistor DT and may be disposed to overlap the first active region ACT1 of the first semiconductor layer SEM1. Although not shown, the first gate electrode GE1 may include a portion of a scan line and/or a portion of an emission line connected to each pixel. The first gate electrode GE1 may be formed as a single layer or multiple layers made of any one of molybdenum (Mo), aluminum (Al), chromium (Cr), gold (Au), titanium (Ti), nickel (Ni), neodymium (Nd), copper (Cu) and an alloy thereof.

The first interlayer insulating layer 140 may be disposed on the first gate electrode GE1. The first interlayer insulating layer 140 may be formed of an inorganic layer, for example, a silicon nitride layer, a silicon oxynitride layer, a silicon oxide layer, a titanium oxide layer, or an aluminum oxide layer. The first interlayer insulating layer 140 may include a plurality of inorganic layers.

A second semiconductor layer SEM2 may be disposed on the first interlayer insulating layer 140. The second semiconductor layer SEM2 may be disposed to be spaced apart from the driving transistor DT in a direction along an interlayer insulating layer, to not overlap in the third direction (Z-axis direction). As not overlapping, elements may be adjacent to each other or spaced apart from each other. The second semiconductor layer SEM2 may include an oxide semiconductor. The second semiconductor layer SEM2 may include a second source region S2, the second active region ACT2, and a second drain region D2.

The second interlayer insulating layer 150 may be disposed on the second semiconductor layer SEM2. The second interlayer insulating layer 150 may be formed of an inorganic layer, for example, a silicon nitride layer, a silicon oxynitride layer, a silicon oxide layer, a titanium oxide layer, or an aluminum oxide layer. The second interlayer insulating layer 150 may include a plurality of inorganic layers.

The second gate electrode GE2 may be disposed on the second interlayer insulating layer 150. The second gate electrode GE2 may be a gate electrode of the switching transistor ST and overlap the second active region ACT2 of the second semiconductor layer SEM2. Although not illustrated, the second gate electrode GE2 may include or be a portion of an initialization voltage line connected to each pixel, a capacitor electrode, and the like. The second gate electrode GE2 may be formed as a single layer or multiple layers made of any one of molybdenum (Mo), aluminum (Al), chromium (Cr), gold (Au), titanium (Ti), nickel (Ni), neodymium (Nd), copper (Cu) and an alloy thereof.

The third interlayer insulating layer 160 may be disposed on the second gate electrode GE2. The third interlayer insulating layer 160 may be formed of an inorganic layer, for example, a silicon nitride layer, a silicon oxynitride layer, a silicon oxide layer, a titanium oxide layer, or an aluminum oxide layer. The third interlayer insulating layer 160 may include a plurality of inorganic layers. One layer or more than one layer among layers 130, 140, 150 and 160 may define an inorganic layer.

The first connection electrode CNE1 may be disposed on the third interlayer insulating layer 160. The first connection electrode CNE1 may be connected to the first drain region D1 of the driving transistor DT, at or through a contact hole penetrating the gate insulating layer 130, the first interlayer insulating layer 140, the second interlayer insulating layer 150, and the third interlayer insulating layer 160. The first connection electrode CNE1 may be formed as a single layer or multiple layers made of any one of molybdenum (Mo), aluminum (Al), chromium (Cr), gold (Au), titanium (Ti), nickel (Ni), neodymium (Nd), copper (Cu) and an alloy thereof.

The first via layer 170 may be disposed on the first connection electrode CNE1. The first via layer 170 may planarize a step caused by profiles of components or layers thereunder. The first via layer 170 may be formed of an organic layer such as acryl resin, epoxy resin, phenolic resin, polyamide resin, polyimide resin and the like.

The second connection electrode CNE2 may be disposed on the first via layer 170, and the second via layer 180 may be disposed on the second connection electrode CNE2. The second connection electrode CNE2 may be connected to the first connection electrode CNE1, at or through a contact hole penetrating the first via layer 170. The second connection electrode CNE2 may be formed as a single layer or multiple layers made of any one of molybdenum (Mo), aluminum (Al), chromium (Cr), gold (Au), titanium (Ti), nickel (Ni), neodymium (Nd), copper (Cu) and an alloy thereof. The second via layer 180 may planarize the stepped portion caused by an underlying profile of the second connection electrode CNE2, and include the same material as the first via layer 170. The first via layer 170 and the second via layer 180 may be a first thickness portion and a second thickness portion of a via layer, respectively.

The light emitting element layer EML may be disposed on the thin film transistor layer TFTL. The light emitting element layer EML may include a first light emitting element ED1 and a bank PDL. The first light emitting element ED1 and the bank PDL may be coplanar with each other, within the light emitting element layer EML The first light emitting element ED1 and the bank PDL may be disposed on the second via layer 180. The first light emitting element ED1 may include a first electrode 210, a light emitting layer 220, and a second electrode 230.

The first electrode 210 may be disposed on the second via layer 180. The first electrode 210 may be connected to the second connection electrode CNE2, at or through a contact hole penetrating the second via layer 180. In a top-emission structure in which light is emitted in a direction toward the second electrode 230 from the light emitting layer 220, the first electrode 210 may be made of or include a metal material having a high reflectivity such as a stack structure of aluminum and titanium (Ti/Al/Ti), a stack structure of aluminum and ITO (ITO/Al/ITO), an APC alloy and a stack structure of APC alloy and ITO (ITO/APC/TO). The APC alloy is an alloy of silver (Ag), palladium (Pd) and copper (Cu).

The bank PDL may be partitioned according to the first electrode 210 on the second via layer 180 to define a first emission area EP1 as a first light emission area. The bank PDL may be formed to cover an edge of the first electrode 210. The bank PDL may be a bank pattern of a solid material formed of an organic layer such as acryl resin, epoxy resin, phenolic resin, polyamide resin, polyimide resin and the like. The bank PDL may represent a black color. The bank PDL may include a dye or a pigment, and may include, for example, carbon black. The solid portions of a bank layer (e.g., the bank PDL) may be spaced apart from each other or disconnected from each other, to define an emission opening therebetween. A respective light emitting element may be disposed in the emission opening of the bank layer. In an embodiment, the sub-display area SDA1 includes a light emission area and a light transmission area adjacent to each other, and a bank PDL covering a portion of the first electrode 210 of the light emitting element and partitioning the light emission area and the light transmission area. The first area FP of the via layer overlaps the light emission area, and the second area SP of the via layer overlaps the light transmission area.

The first emission area EP1 is an area (e.g., a planar area) in which the first electrode 210, the light emitting layer 220, and the second electrode 230 are sequentially stacked such that the holes from the first electrode 210 and the electrons from the second electrode 230 are combined with each other to emit light.

The light emitting layer 220 is formed on the first electrode 210 and the bank PDL. The light emitting layer 220 may include an organic material to emit light in a predetermined color. For example, the light emitting layer 220 may include a hole transporting layer, an organic material layer, and an electron transporting layer. In addition, the light emitting layer 220 may further include a hole injection layer, an electron injection layer, a charge generation layer, and the like.

The second electrode 230 may be formed on the light emitting layer 220. The second electrode 230 may be formed to cover the light emitting layer 220. The second electrode 230 may be a common layer that is commonly formed in the pixels PX. That is, the second electrode 230 may extend from one pixel PX to an adjacent pixel, as a unitary layer. A capping layer (not shown) may be further formed on the second electrode 230, such that the first electrode 210, the light emitting layer 220, the second electrode 230 and the capping layer are sequentially stacked.

In the top emission structure, the second electrode 230 may be formed of transparent conductive oxide (TCO) such as indium tin oxide (ITO) and indium zinc oxide (IZO) capable of transmitting light or a semi-transmissive conductive material such as magnesium (Mg), silver (Ag), or an alloy of magnesium (Mg) and silver (Ag). When the second electrode 230 is formed of a semi-transmissive conductive material, the light emission efficiency can be increased due to a micro-cavity effect.

The encapsulation layer TFE may be disposed on the light emitting element layer EML. The encapsulation layer TFE may include at least one inorganic layer to prevent oxygen or moisture from permeating into the light emitting element layer EML. In addition, the encapsulation layer TFE includes at least one organic layer to protect the light emitting element layer EML from foreign substances such as dust. For example, the encapsulation layer TFE may include a first inorganic layer TFE1, an organic layer TFE2, and a second inorganic layer TFE3.

The first inorganic layer TFE1 may be disposed on the second electrode 230, the organic layer TFE2 may be disposed on the first inorganic layer TFE1, and the second inorganic layer TFE3 may be disposed on the organic layer TFE2. The first inorganic layer TFE1 and the second inorganic layer TFE3 may be formed of multiple layers in which one or more inorganic layers of a silicon nitride layer, a silicon oxynitride layer, a silicon oxide layer, a titanium oxide layer and an aluminum oxide layer are alternately stacked. The organic layer TFE2 may be a monomer.

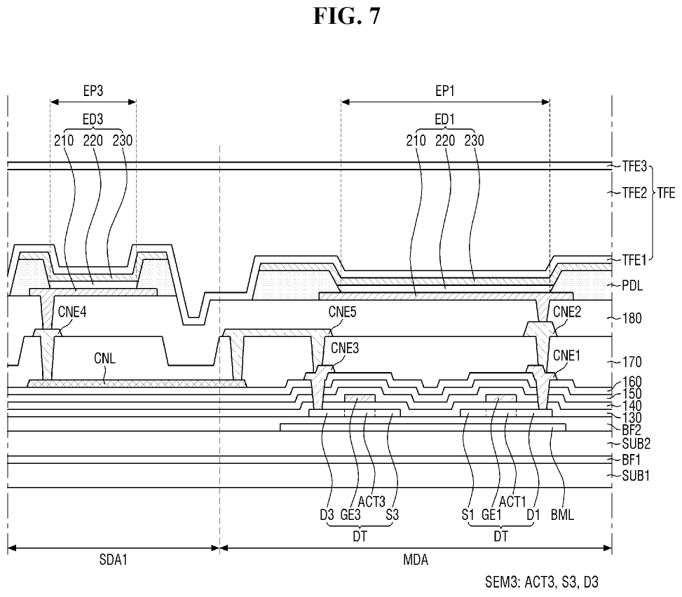

FIG. 7 is an enlarged cross-sectional view of a display panel 300 according to an embodiment. FIG. 7 shows a cross section of a first pixel PX1 disposed in the main display area MDA and a cross section of a third pixel PX3 disposed in the first sub-display area SDA1 of FIG. 5. Similar to FIG. 6 above, the horizontal direction in FIG. 7 may represent various directions along the plane defined by the first and second directions crossing each other, while the vertical direction may represent the thickness direction.

Referring to FIG. 7 in conjunction with FIG. 6, a third semiconductor layer SEM3 may be disposed on the second buffer layer BF2 in the main display area MDA. The third semiconductor layer SEM3 may be disposed in the third pixel circuit CP3 of FIG. 5. The third semiconductor layer SEM3 may include a third source region S3, a third active region ACT3, and a third drain region D3 by ion doping.

A third gate electrode GE3 may be disposed on the gate insulating layer 130. The third gate electrode GE3 may be disposed to overlap the third active region ACT3 of the third semiconductor layer SEM3. The third gate electrode GE3 may be disposed on (or in) the same layer as the first gate electrode GE1. As being in a same layer, elements may be formed in a same process and/or include a same material as each other, elements may be respective portions of a same material layer, elements may be on a same layer by forming an interface with a same underlying or overlying layer, etc., without being limited thereto.

A first interlayer insulating layer 140, a second interlayer insulating layer 150, and a third interlayer insulating layer 160 may be disposed on the third gate electrode GE3, and a third connection electrode CNE3 may be disposed on the third interlayer insulating layer 160. The third connection electrode CNE3 may be connected to the third drain region D3 of the third semiconductor layer SEM3 at or through a contact hole penetrating the gate insulating layer 130, the first interlayer insulating layer 140, the second interlayer insulating layer 150, and the third interlayer insulating layer 160. The third connection electrode CNE3 may be disposed on the same layer as the first connection electrode CNE1.

A connection line CNL may be disposed on the third interlayer insulating layer 160 in the first sub-display area SDA1. The connection line CNL may be disposed to extend from the main display area MDA to the first sub-display area SDA1. The connection line CNL may transmit a driving signal from the driving transistor DT of the third pixel circuit CP3. As described above, the connection line CNL may be formed of a transparent conductive line to secure transmittance of light. The connection line CNL may be disposed on the same layer as the third connection electrode CNE3.

The first via layer 170 may be disposed on the connection lines and the third connection electrode CNE3, and a fourth connection electrode CNE4 and a fifth connection electrode CNE5 may be disposed on the first via layer 170. The fourth connection electrode CNE4 may be connected to the connection line CNL at or through a contact hole penetrating the first via layer 170, in the first sub-display area SDA1. The fifth connection electrode CNE5 may be disposed in the main display area MDA. The fifth connection electrode CNE5 may be connected to the third connection electrode CNE3 of the driving transistor DT of the third pixel circuit CP3, at a first end of the fifth connection electrode CNE5, at or through a contact hole passing through the first via layer 170. In addition, the fifth connection electrode CNE5 may be connected to the connection line CNL, at a second end of the fifth connection electrode CNE5 which is opposite to the first end, at or through a contact hole penetrating the first via layer 170. Accordingly, the fifth connection electrode CNE5 may transfer the driving signal of the driving transistor DT of the third pixel circuit CP3, to the connection line CNL. The fifth connection electrode CNE5 may be disposed on the same layer as the second connection electrode CNE2 and/or the fourth connection electrode CNE4.

A third light emitting element ED3 may be disposed on the second via layer 180, in the first sub-display area SDA1. The third light emitting element ED3 may include a first electrode 210, a light emitting layer 220 and a second electrode 230.

Specifically, the first electrode 210 of the third light emitting element ED3 may be disposed on the second via layer 180. The first electrode 210 may be connected to the fourth connection electrode CNE4 at or through a contact hole penetrating the second via layer 180. Accordingly, the first electrode 210 may receive the driving signal of the driving transistor DT, through the connection line CNL connected to the fourth connection electrode CNE4. That is, the sub-display area SDA may include a connection electrode which is between the via layer and the first electrode 210, where the connection electrode together with the connection line CNL connects the transistor to the light emitting element.

The bank PDL defining a third emission area EP3 as a third light emission area may be disposed on a second via layer VIA2 to cover an edge of the first electrode 210 of the third light emitting element ED3. The light emitting layer 220 may be disposed on the bank PDL and the first electrode 210 of the third light emitting element ED3, and the second electrode 230 may be disposed on the light emitting layer 220.

In the first sub-display area SDA1, the third light emitting element ED3 may be disposed on the second via layer 180.

As described above, in the sub-display areas SDA1, SDA2, SDA3, and SDA4 except the main display area MDA, light incident from the outside may be transmitted to the optical devices 740, 750, 760, and 770 (in FIG. 2) disposed thereunder. For the sensing characteristics of each optical device, the level of the light transmittance of the sub-display areas SDA1, SDA2, SDA3, and SDA4 is maximized.

Hereinafter, in the present embodiments, a display device 10 capable of improving light transmittance of the sub-display areas SDA1, SDA2, SDA3, and SDA4 will be described.

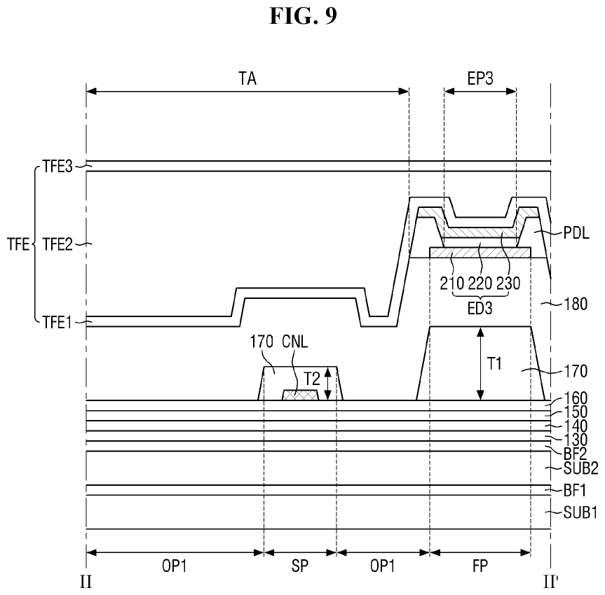

FIG. 8 is a cross-sectional view taken along line I-I′ of FIG. 5. FIG. 9 is a cross-sectional view taken along line II-II′ of FIG. 5. FIG. 8 shows enlarged cross-sections of light emitting elements and connection lines disposed in the first sub-display area SDA1, and FIG. 9 shows cross-sections of the third light emitting element ED3 disposed in the first sub-display area SDA1 and the surrounding area. The views of FIGS. 8 and 9 may be taken together in an embodiment, without being limited thereto.

The first light emitting element ED1 and the third light emitting element ED3 as adjacent light emitting elements in the first sub-display area SDA1 will be described below as an example, but the same will be applied to the second light emitting element ED2 disposed in the first sub-display area SDA1. In addition, a redundant description will be omitted in the description in conjunction with FIGS. 6 and 7.

Referring to FIGS. 8 and 9, according to an embodiment, in the first sub-display area SDA1, the first via layer 170 and the second via layer 180 may be disposed on the third interlayer insulating layer 160, and light emitting elements ED1 and ED3 may be disposed on the second via layer 180. The connection line CNL extending from the main display area MDA, may be disposed on the third interlayer insulating layer 160 and electrically connected to the third light emitting element ED3 in the first sub-display area SDA1.

The bank PDL surrounding the first light emitting element ED1 may define the first emission area EP1, and the bank PDL surrounding the third light emitting element ED3 defines the third emission area EP3. The transmission area TA may be defined as a planar area other than the planar areas occupied by the first emission area EP1, third emission area EP3, and the banks PDL surrounding the first emission area EP1 and the third emission area EP3.

Since the material constituting the first via layer 170 has a high absorbance of short-wavelength light, that is, blue-colored light, the intensity of short-wavelength light detected by optical devices receiving light through the first via layer 170 may be low. Also, loss of light may occur due to a difference in refractive index between the first via layer 170 and the third interlayer insulating layer 160 thereunder. Accordingly, the first via layer 170 may have a different thickness for each area to increase the light transmittance of the first sub-display area SDA1.

Specifically, the first via layer 170 may include a first area FP and a second area SP, and a first opening area OP1 as a first opening defined in the first via layer 170. The first area FP may be an area of the first via layer 170 that overlaps each of the first electrodes 210 of the light emitting elements ED1 and ED3. The second area SP may be an area of the first via layer 170 that does not overlap each of the first electrodes 210 of the light emitting elements ED1 and ED3, and overlaps the connection line CNL. The first opening area OP1 is a portion other than the first area FP and the second area SP, and a material of the first via layer 170 is not disposed at the first opening area OP1 to expose the third interlayer insulating layer 160 thereunder to outside the first via layer 170. In an embodiment, the via layer includes a first area FP overlapping the first electrode 210, and a second area SP overlapping the connection line CNL together with not overlapping the first electrode 210. An opening (e.g., at the first opening area OP1) is defined in the via layer, and the opening overlaps the light transmission area together with not overlapping the first area FP or the second area SP of the via layer. An interlayer insulating layer is between the substrate and the connection line CNL and the opening which is defined in the via layer exposes the interlayer insulating layer to outside the via layer.

Each first area FP of the first via layer 170 may overlap the first electrode 210 of the first light emitting element ED1 and the first electrode 210 of the third light emitting element ED3, in the third direction (Z-axis direction), respectively. Also, the first area FP of the first via layer 170 may overlap the first emission area EP1 and the third emission area EP3. The first area FP of the first via layer 170 may be an area in which the first electrodes 210 are formed, and may be thick enough so that the first electrode 210 is formed to be flat. For example, the first area FP of the first via layer 170 may have a thickness which is substantially the same thickness as a thickness of the via layer material which is initially coated and cured on the underlying insulating layer. In addition, the thickness of the first via layer 170 at the first area FP may be the same as the thickness of the first via layer 170 at the main display area MDA.

Each second area SP of the first via layer 170 may not overlap the first electrode 210 of the first light emitting element ED1 and the first electrode 210 of the third light emitting element ED3 in the third direction (Z-axis direction), respectively. The second area SP of the first via layer 170 may overlap the transmission area TA in the third direction (Z-axis direction). The second area SP of the first via layer 170 may overlap the connection line CNL in the third direction (Z-axis direction).

Referring to FIGS. 8 and 9, for example, a material portion of the first via layer 170 may extend along the upper surface and side surfaces (or sidewalls) of the connection line CNL. Although not shown, the material portion of the first via layer 170 may extend along the upper surface and the side surfaces (or sidewalls) of the connection line CNL in the main display area MDA, similar to that shown for the first sub-display area SDA1.

Referring to FIGS. 8 and 9, for example, a via layer may have a total thickness as including thickness portions of both the first via layer 170 and the second via layer 180, at respective locations along the insulating layer (e.g., the third interlayer insulating layer 160). The total thickness of the via layer may be minimum at the second area SP and/or the first opening area OP1. The total thickness of the via layer may be maximum at an area other than at the second area SP and/or the first opening area OP1, such as at the first area FP.

The connection line CNL may be connected to the first electrode 210 of each light emitting element, through the fourth connection electrode CNE4. When the first via layer 170 is not formed on the connection line CNL, the thickness of the second via layer 180 may be formed to be thick, so that the level difference may be large. Due to this step difference, it is difficult to form a pattern of the first electrode 210 and a short circuit may occur due to residues of the pattern of the first electrode 210. Accordingly, the first via layer 170 at the second area SP may be formed to have a predetermined thickness smaller than the thickness of the first via layer 170 at the first area FP.

The first opening area OP1 of the first via layer 170 may correspond to areas other than the first area FP and the second area SP. The first opening area OP1 of the first via layer 170 may not overlap each of the emission areas EP1 and EP3, the first electrodes 210, and the connection line CNL in the third direction (Z-axis direction). Also, the first opening area OP1 of the first via layer 170 may overlap the transmission area TA in a third direction (Z-axis direction). The first opening area OP1 of the first via layer 170 may expose the third interlayer insulating layer 160 of a bottom stack of layers within the thin film transistor layer TFTL, to outside the first via layer 170 of a top stack of layer within the thin film transistor layer TFTL.

The first area FP of the first via layer 170 may be a first thickness portion of the first via layer 170 having a first thickness T1, and the second area SP may be a second thickness portion of the first via layer 170 having a second thickness T2. The first thickness T1 of the first area FP may be greater than the second thickness T2 of the second area SP. In an embodiment of a method of providing a display panel 300, the first and the second areas FP and SP and the first opening area OP1 of the first via layer 170 may be formed using a halftone mask. For example, the first area FP of the first via layer 170 may be an area in which via layer material remains as being unexposed during the method, the second area SP may be an area in which via layer material partially remains as being partially exposed during the method, and the first opening area OP1 may be an area from which the via layer material is removed as being completely exposed during the method. Accordingly, the first thickness T1 of the first area FP of the first via layer 170 may be greater than the second thickness T2 of the second area SP.

According to an embodiment, as the first via layer 170 is formed to include the second area SP and the first opening area OP1 in the transmission area TA, the transmittance of light incident to optical devices 740, 750, 760, and 770 (in FIG. 2) through the transmission area TA may be improved. In particular, by forming the second area SP of the first via layer 170 having the second thickness T2 in the area overlapping the connection line CNL, an electrical short circuit due to pattern defect of the first electrode 210 may be prevented while improving the light transmittance at the second area SP. The thickness of the first via layer 170 at the transmission area TA is smaller than the thickness at the light emission layer, by the smaller thickness portion at the first thickness T1 and/or the absence of material of the first via layer 170 at the first opening area OP1. That is, in an embodiment, the via layer has a first thickness T1 overlapping the first electrode 210 together with having a second thickness T2 which overlaps the connection line CNL and is smaller than the first thickness T1.

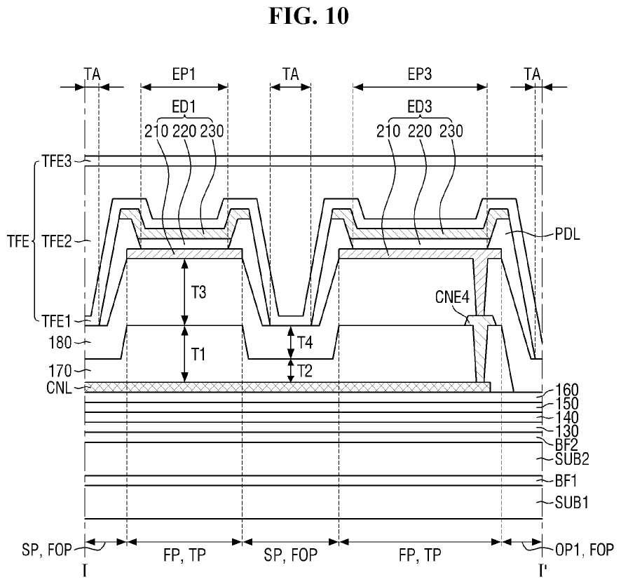

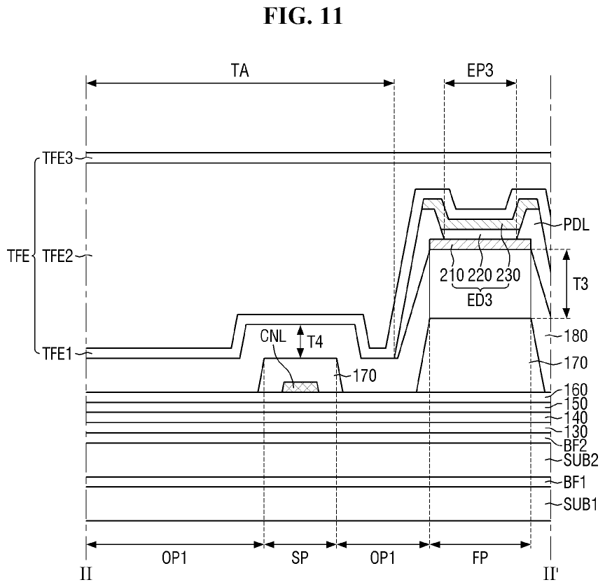

FIG. 10 is a cross-sectional view showing an embodiment of the display panel 300 taken along line I-I′ of FIG. 5, and FIG. 11 is a cross-sectional view showing an embodiment of the display panel 300 taken along line II-II′ of FIG. 5. The views of FIGS. 10 and 11 may be taken together in an embodiment, without being limited thereto.

The embodiments of FIGS. 10 and 11 are different from the embodiments of FIGS. 8 and 9 described above, in that, in the first sub-display area SDA1, the second via layer 180 further includes a third area TP and a fourth area FOP. Hereinafter, redundant description of the above-described embodiments of FIGS. 8 and 9 will be omitted while focusing on differences.

Referring to FIGS. 10 and 11, in the first sub-display area SDA1, the first via layer 170 may include a first area FP having a first thickness T1, a second area SP having a second thickness T2, and a first opening area OP1. The second via layer 180 disposed on the first via layer 170 may include a third area TP having a third thickness T3 and a fourth area FOP having a fourth thickness T4.

Since the material constituting the second via layer 180 has a high absorbance of blue-colored light, similar to the above-described first via layer 170, the intensity of short-wavelength light detected by optical devices receiving light through the second via layer 180 may be low. Accordingly, the second via layer 180 may also have a different thickness for each area to increase the light transmittance of the first sub-display area SDA1.

Specifically, the second via layer 180 may include the third area TP and the fourth area FOP. The third area TP may be an area that overlaps each first electrode 210 of the light emitting elements ED1 and ED3. The fourth area FOP may be an area other than the third area TP, that is, a remaining area of the second via layer 180.

Each third area TP of the second via layer 180 may overlap the first electrode 210 of the first light emitting element ED1 and the first electrode 210 of the third light emitting element ED3 in the third direction (Z-axis direction), respectively. Also, the third area TP of the second via layer 180 may overlap the first emission area EP1 and the third emission area EP3. The third area TP of the second via layer 180 may be an area in which the first electrodes 210 are formed thereon, and may be thick enough so that the first electrode 210 is formed to be flat. For example, third area TP of the second via layer 180 may have substantially the same thickness as the thickness of the via layer material coated and cured. In addition, the thickness of the third area TP of the second via layer 180 may be the same as the thickness of the second via layer 180 in the main display area MDA. The third area TP of the second via layer 180 may overlap the first area FP of the first via layer 170, and not overlap both of the second area SP and the first opening area OP1 of the first via layer 170.

Each fourth area FOP of the second via layer 180 may not overlap the first electrode 210 of the first light emitting element ED1 and the first electrode 210 of the third light emitting element ED3, in the third direction (Z-axis direction), respectively. The fourth area FOP of the second via layer 180 may overlap the transmission area TA in the third direction (Z-axis direction), and may overlap the connection line CNL in the third direction (Z-axis direction). As described above, when the total thickness of the via layer which is at the top portion of the connection line CNL is thick, forming a pattern of the first electrode 210 may be difficult due to the step difference, and an electrical short circuit may occur due to conductive residue of the conductive pattern of the first electrode 210. Accordingly, the second via layer 180 of the fourth area FOP may be formed to have a predetermined thickness smaller than the thickness of the third area TP.

In addition, the fourth area FOP of the second via layer 180 may correspond to a remaining area of the second via layer 180 other than the third area TP. At least a portion of the fourth area FOP of the second via layer 180 may be in contact with the top surface of the third interlayer insulating layer 160 which is exposed to outside the first via layer 170 by the first opening area OP1 of the first via layer 170. As being in contact, elements may form an interface therebetween, without being limited thereto.

The third area TP of the second via layer 180 may be formed to have a third thickness T3, and the fourth area FOP may be formed to have a fourth thickness T4. The third thickness T3 of the third area TP may be greater than the fourth thickness T4 of the fourth area FOP. The third thickness T3 and the fourth thickness T4 may be defined from a surface of an underlying layer (e.g., the third interlayer insulating layer 160 or the first via layer 170), at respective locations along the thin film transistor layer TFTL.

In an embodiment of a method of providing the display panel 300, the third area TP and fourth area FOP of the second via layer 180 may be formed using a halftone mask. For example, the third area TP of the second via layer 180 may be an area in which via layer material remains as being unexposed, and the fourth area FOP may be an area in which via layer material partially remains as being partially exposed. Accordingly, the third thickness T3 of the second via layer 180 of the third area TP may be greater than the fourth thickness T4 of the second via layer 180 of fourth area FOP, within a total thickness of the via layer at the respective location along the thin film transistor layer TFTL.

According to an embodiment, as the second via layer 180 is formed to include the fourth area FOP in the transmission area TA, the transmittance of light incident to optical devices 740, 750, 760, and 770 (in FIG. 2) through the transmission area TA may be improved. In particular, by forming the fourth area FOP of the second via layer 180 having the fourth thickness T4 in the area overlapping the connection line CNL, an electrical short circuit due to pattern defect of first electrode 210 may be prevented while improving the light transmittance.

In addition, the second via layer 180 may form the fourth area FOP overlapping the second area SP and the first opening area OP1 defining small thickness portions of the first via layer 170 in the transmission area TA, thereby further improving the light transmittance.

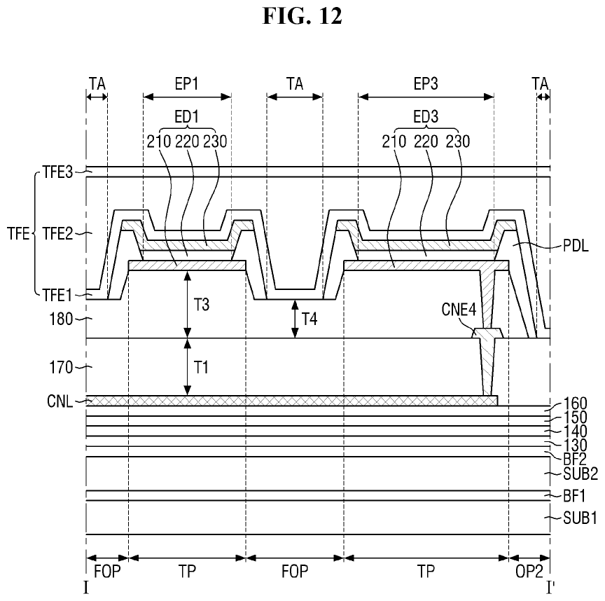

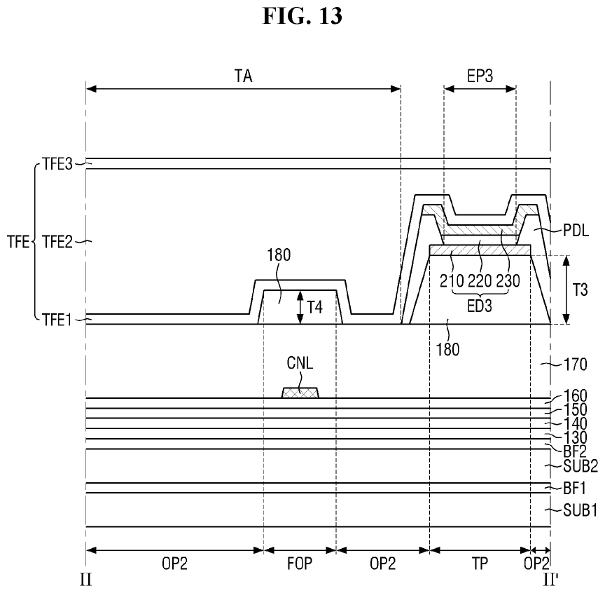

FIG. 12 is a cross-sectional view showing an embodiment of the display panel taken 300 along line I-I′ of FIG. 5. FIG. 13 is a cross-sectional view showing an embodiment of the display panel 300 taken along line II-II′ of FIG. 5. The views of FIGS. 12 and 13 may be taken together in an embodiment, without being limited thereto.

The via layer as one or more of the first via layer 170 and the second via layer 180, is continuously disposed in the main display area MDA and the sub-display area SDA. The first thickness T1 of the via layer is the same as the thickness in the main display area MDA. That is, the via layer is in the sub-display area SDA and extends from the sub-display area SDA and into the main display area MDA, such that the first thickness T1 of the via layer in the sub-display area SDA is the same as a thickness of the via layer in the main display area MDA.

The embodiments of FIGS. 12 and 13 are different from the embodiments of FIGS. 8 to 11 described above, in that, in the first sub-display area SDA1, the first via layer 170 is formed to have a uniform or constant thickness but the second via layer 180 includes a third area TP, a fourth area FOP, and a second opening area OP2 as a second opening. Hereinafter, redundant description of the above-described embodiments of FIGS. 8 to 11 will be omitted while focusing on differences.

Referring to FIGS. 12 and 13, in the first sub-display area SDA1, the first via layer 170 may have the same thickness as the main display area MDA. The second via layer 180 disposed on the first via layer 170 may include a third area TP having a third thickness T3, a fourth area FOP having a fourth thickness T4, and a second opening area OP2 defined in the second via layer 180.

Specifically, the second via layer 180 may include a third area TP, a fourth area FOP, and a second opening area OP2. Since the third area TP is the same as the third area TP of FIGS. 10 and 11 described above, the description thereof will be omitted.

Each fourth area FOP of the second via layer 180 may not overlap the first electrode 210 of the first light emitting element ED1 and the first electrode 210 of the third light emitting element ED3 in the third direction (Z-axis direction), respectively. The fourth area FOP of the second via layer 180 may overlap the transmission area TA in the third direction (Z-axis direction). The fourth area FOP of the second via layer 180 may overlap the connection line CNL in the third direction (Z-axis direction). As described above, when the thickness of the via layer extended along the top portion of the connection line CNL is thick, forming a pattern of the first electrode 210 may be difficult due to the step difference and an electrical short circuit may occur due to conductive residue of the pattern of the first electrode 210. Accordingly, the second via layer 180 of the fourth area FOP may be formed to have a predetermined thickness smaller than the thickness of the third area TP.

The second opening area OP2 of the second via layer 180 may correspond to the remaining area of the second via layer 180 other than the third area TP and the fourth area FOP. The second opening area OP2 of the second via layer 180 may not overlap each of the emission areas EP1 and EP3, the first electrode 210, and the connection line CNL in the third direction (Z-axis direction). Also, the second opening area OP2 of the second via layer 180 may overlap the transmission area TA in a third direction (Z-axis direction). The second opening area OP2 of the second via layer 180 may expose the first via layer 170 to outside the second via layer 180.

The third area TP, the fourth area FOP, and the second opening area OP2 of the second via layer 180 may be disposed at respective locations along the first via layer 170, and may overlap the first via layer 170. Since the first via layer 170 has a constant thickness, a variation in total thickness of the collective via layer (e.g., the first via layer 170 together with the second via layer 180) may be effectively defined by the presence or absence of material of the second via layer 180. In the present embodiment, the thickness of the first via layer 170 may be the same in an area overlapping the third area TP, the fourth area FOP, and the second opening area OP2 of the second via layer 180. That is, the first via layer 170 may have the same thickness as the first via layer 170 of FIGS. 8 to 11 described above.

The third area TP of the second via layer 180 may be formed to have a third thickness T3, and the fourth area FOP may be formed to have a fourth thickness T4. The third thickness T3 of the third area TP may be greater than the fourth thickness T4 of the fourth area FOP. In an embodiment of a method of providing the display panel 300, the third area TP, the fourth area FOP and the second opening area OP2 of the second via layer 180 may be formed using a halftone mask. For example, the third area TP of the second via layer 180 may be an area in which via layer material remains as being unexposed, the fourth area FOP may be an area in which via layer material partially remains as being partially exposed, and the second opening area OP2 may be an area from which the via layer material is removed as being completely exposed. Accordingly, the third thickness T3 of the second via layer 180 of the third area TP may be greater than the fourth thickness T4 of the fourth area FOP.

According to an embodiment, as the second via layer 180 is formed to include the fourth area FOP and the second opening area OP2 in the transmission area TA, the transmittance of light incident to optical devices 740, 750, 760, and 770 (in FIG. 2) through the transmission area TA may be improved. In particular, by forming the fourth area FOP of the second via layer 180 having the fourth thickness T4 in the area overlapping the connection line CNL, an electrical short circuit due to pattern defect of first electrode 210 may be prevented while improving the light transmittance. Further, light transmittance in the transmission area TA may be further improved by forming the thickness of the second via layer 180 differently for each area among the transmission area TA and the light emission area, or removing the second via layer 180 completely at respective areas while maintaining the thickness of the first via layer 170 at such respective areas.

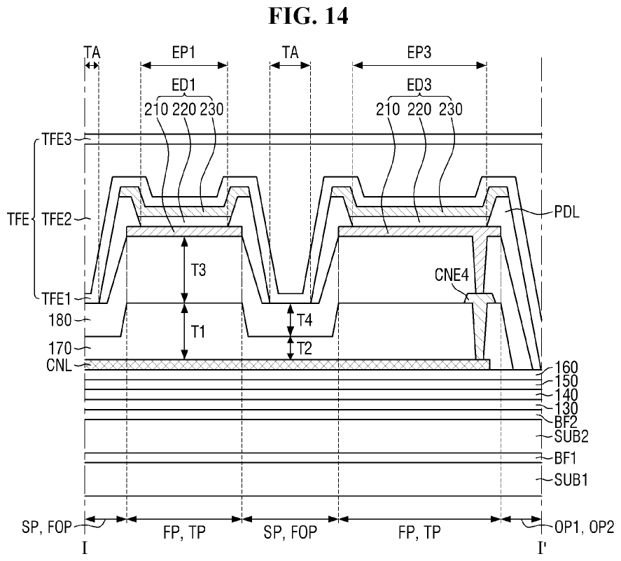

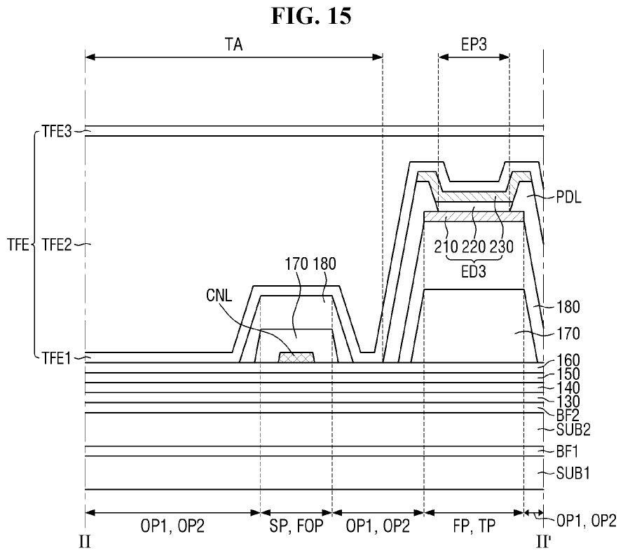

FIG. 14 is a cross-sectional view showing an embodiment of the display panel 300 taken along line I-I′ of FIG. 5, and FIG. 15 is a cross-sectional view showing an embodiment of the display panel 300 taken along line II-II′ of FIG. 5.

The embodiments of FIGS. 14 and 15 are different from the embodiments of FIGS. 10 and 11 described above, in that, in the first sub-display area SDA1, the second via layer 180 further includes a second opening area OP2. Hereinafter, redundant description of the above-described embodiments of FIGS. 10 and 11 will be omitted while focusing on differences.

Referring to FIGS. 14 and 15, in the first sub-display area SDA1, the first via layer 170 may include a first area FP having a first thickness T1, a second area SP having a second thickness T2, and a first opening area OP1. The second via layer 180 disposed on the first via layer 170 may include a third area TP having a third thickness T3, a fourth area FOP having a fourth thickness T4, and a second opening area OP2 corresponding to the first opening area OP1.

The second opening area OP2 of the second via layer 180 may correspond to the remaining area other than the third area TP and the fourth area FOP. The second opening area OP2 of the second via layer 180 may not overlap each of the emission areas EP1 and EP3, the first electrode 210, and the connection line CNL in the third direction (Z-axis direction). Also, the second opening area OP2 of the second via layer 180 may overlap the transmission area TA and the first opening area OP1 in the third direction (Z-axis direction). The second opening area OP2 of the second via layer 180 may expose the third interlayer insulating layer 160 exposed by the first opening area OP1 of the first via layer 170.

In the present embodiment, by further including the second opening area OP2 of the second via layer 180 that overlaps the first opening area OP1 of the first via layer 170 in the transmission area TA, the transmittance of light incident to optical devices (740, 750, 760, and 770 in FIG. 2) through the transmission area TA may be further improved.

In concluding the detailed description, those skilled in the art will appreciate that many variations and modifications can be made to the embodiments without substantially departing from the principles of the invention. Therefore, the disclosed embodiments of the invention are used in a generic and descriptive sense only and not for purposes of limitation.

What is claimed is:

1. A display device comprising:
a main display area and a sub-display area adjacent to each other;
a transistor in the main display area;
a light emitting element which is in the sub-display area and electrically connected to the transistor, the light emitting element comprising a first electrode, a light emitting layer and a second electrode;
a connection line which extends from the main display area to the sub-display area and connects the transistor to the light emitting element; and
a via layer between the transistor and the light emitting element,
wherein the via layer has a first thickness overlapping the first electrode together with having a second thickness which overlaps the connection line and is smaller than the first thickness.

2. The display device of claim 1, wherein the via layer comprises:
a first area overlapping the first electrode, and
a second area overlapping the connection line together with not overlapping the first electrode.

3. The display device of claim 2, wherein the first area of the via layer has the first thickness and the second area of the via layer has the second thickness.

4. The display device of claim 2, wherein the connection line overlaps the first area and the second area of the via layer.

5. The display device of claim 2, further comprising:
a light emission area and a light transmission area adjacent to each other, and
a bank covering a portion of the first electrode of the light emitting element and partitioning the light emission area and the light transmission area,
wherein
the first area of the via layer overlaps the light emission area, and
the second area of the via layer overlaps the light transmission area.

6. The display device of claim 2, further comprising a light emission area and a light transmission area adjacent to each other,
wherein,
an opening is defined in the via layer, and
the opening overlaps the light transmission area together with not overlapping the first area or the second area of the via layer.

7. The display device of claim 6, further comprising:
a substrate in the main display area and the sub-display area; and
an interlayer insulating layer between the substrate and the connection line,
wherein the opening which is defined in the via layer exposes the interlayer insulating layer to outside the via layer.

8. The display device of claim 5, wherein the first area of the via layer overlaps the light emission area.

9. The display device of claim 1, wherein
the via layer is in the sub-display area and extends from the sub-display area and into the main display area, and
wherein the first thickness of the via layer in the sub-display area is the same as a thickness of the via layer in the main display area.

10. The display device of claim 1, further comprising a connection electrode which is between the via layer and the first electrode, wherein the connection electrode together with the connection line connects the transistor to the light emitting element.

11. The display device of claim 1, wherein the connection line comprises a transparent conductive oxide.

12. A display device comprising:
a main display area and a sub-display area adjacent to each other;
a transistor in the main display area;
a light emitting element which is in the sub-display area and electrically connected to the transistor, the light emitting element comprising a first electrode, a light emitting layer and a second electrode;
a connection line which extends from the main display area to the sub-display area and connects the transistor to the light emitting element; and
in order from the connection line to the light emitting element, a first via layer and a second via layer,
wherein each of the first via layer and the second via layer has a thickness overlapping the connection line which is smaller than a thickness overlapping the first electrode.

13. The display device of claim 12, wherein
the first via layer comprises a first area overlapping the first electrode in the sub-display area, and a second area overlapping the connection line together with not overlapping the first electrode, and
the second via layer comprises a third area overlapping the first electrode in the sub-display area, and a fourth area overlapping the connection line together with not overlapping the first electrode.

14. The display device of claim 13, wherein
within the first via layer, the first area has a first thickness and the second area has a second thickness smaller than the first thickness, and
within the second via layer, the third area has a third thickness and the fourth area has a fourth thickness smaller than the third thickness.

15. The display device of claim 13, wherein
the first area of the first via layer overlaps the third area of the second via layer, and
the second area of the first via layer overlaps the fourth area of the second via layer.

16. The display device of claim 13, further comprising:
a light emission area and a light transmission area adjacent to each other, and
a bank covering a portion of the first electrode and partitioning the light emission area and the light transmission area,
wherein
the first area of the first via layer and the third area of the second via layer each overlaps the light emission area, and
the second area of the first via layer and the fourth area of the second via layer each overlaps the light transmission area.

17. The display device of claim 16, wherein
a first opening is defined in the first via layer, the first opening area in an area of the first via layer other than the first area and the second area, and
the first opening which is defined in the first via layer overlaps the fourth area of the second via layer together with overlapping the light transmission area.

18. The display device of claim 17, further comprising:
a substrate in the main display area and the sub-display area; and
an interlayer insulating layer between the substrate and the connection line,
wherein
the first opening which is defined in the first via layer exposes the interlayer insulating layer to outside the first via layer, and
the second via layer is in contact with the interlayer insulating layer.

19. The display device of claim 16, wherein
a first opening is defined in the first via layer, the first opening in an area of the first via layer other than the first area and the second area,
a second opening is defined in the second via layer, the second opening in an area of the second via layer other than the third area and the fourth area, and
the first opening of the first via layer and the second opening of the second via layer overlap each other.

20. A display device comprising:
a main display area and a sub-display area adjacent to each other;
a transistor in the main display area;
a light emitting element which is in the sub-display area and electrically connected to the transistor, the light emitting element comprising a first electrode, a light emitting layer and a second electrode;
a connection line which extends from the main display area to the sub-display area and connects the transistor to the light emitting element; and
in order from the connection line to the light emitting element, a first via layer and a second via layer,
wherein the second via layer has a first thickness overlapping the first electrode together with a second thickness which overlaps the connection line and is smaller than the first thickness.

21. The display device of claim 20, wherein
the second via layer comprises a first area overlapping the first electrode in the sub-display area, and a second area which overlaps the connection line together with not overlapping the first electrode, and
the first area of the second via layer has the first thickness and the second area of the second via layer has the second thickness.

22. The display device of claim 21, further comprising:
a light emission area and a light transmission area adjacent to each other, and
a bank covering a portion of the first electrode and partitioning the light emission area and the light transmission area,
wherein
the first area of the second via layer overlaps the light emission area, and
the second area of the second via layer overlaps the light transmission area.

23. The display device of claim 22, wherein
an opening is defined in the second via layer, and
the opening overlaps the light transmission area together with not overlapping the first area or the second area of the second via layer.

24. The display device of claim 23, wherein a thickness of the first via layer is the same at each of the first area, the second area and the opening of the second via layer.
